(19) United States
(12) Patent Application Publication
(10) Pub. No.: US 2025/0227920 A1
(43) Pub. Date: Jul. 10, 2025

(54) SEMICONDUCTOR DEVICE

(71) Applicant: SAMSUNG ELECTRONICS CO., LTD., Suwon-si (KR)

(72) Inventor: Yeonjin LEE, Suwon-si (KR)

(73) Assignee: SAMSUNG ELECTRONICS CO., LTD., Suwon-si (KR)

(21) Appl. No.: 19/005,638

(22) Filed: Dec. 30, 2024

(30) Foreign Application Priority Data
Jan. 9, 2024 (KR) 10-2024-0003635

(51) Int. Cl. H10B 12/00

(52) U.S. Cl. CPC H10B 12/488; H10B 12/482

(57) ABSTRACT

A semiconductor device include a word line on a substrate and extending in a first direction perpendicular to a surface of the substrate, a plurality of channel regions at least partially surrounding the word line and spaced apart from each other in the first direction, a bit line at one side of the plurality of channel regions, and extending in a second direction perpendicular to the first direction, and a plurality of capacitor structures at least partially surrounding the word line, where the plurality of capacitor structures and the plurality of channel regions are aligned in the first direction and the plurality of capacitor structures are spaced apart from the plurality of channel regions in the first direction.

### CROSS-REFERENCE TO RELATED APPLICATION

This application is based on and claims priority under 35 U.S.C. § 119 to Korean Patent Application No. 10-2024-0003635, filed on Jan. 9, 2024, in the Korean Intellectual Property Office, the disclosure of which is incorporated by reference herein in its entirety.

### BACKGROUND

Example embodiments of the disclosure relate to a semiconductor device including semiconductor memory elements arranged in three dimensions.

As the miniaturization, multi-functionalization, and high-performance of electronic products are required, high-capacity semiconductor memory elements are required. In order to provide the high-capacity semiconductor memory elements, the increased degree of integration is required. Since the degree of integration of two-dimensional semiconductor memory elements is mainly determined by the area occupied by a unit memory cell, the degree of integration of the two-dimensional semiconductor memory elements is increasing but is still limited.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with an improved degree of integration.

Additional aspects will be set forth in part in the description which follows and, in part, will be apparent from the description, or may be learned by practice of the presented embodiments.

According to an aspect of an example embodiment, a semiconductor device may include a word line on a substrate and extending in a first direction perpendicular to a surface of the substrate, a plurality of channel regions at least partially surrounding the word line and spaced apart from each other in the first direction, a bit line at one side of the plurality of channel regions, and extending in a second direction perpendicular to the first direction, and a plurality of capacitor structures at least partially surrounding the word line, where the plurality of capacitor structures and the plurality of channel regions are aligned in the first direction, and the plurality of capacitor structures are spaced apart from the plurality of channel regions in the first direction.

According to an aspect of an example embodiment, a semiconductor device may include a plurality of word lines on a substrate and extending in a first direction perpendicular to a surface of the substrate, the plurality of word lines arranged in a second direction intersecting the first direction and a third direction intersecting the second direction, where each word line of the plurality of word lines is at least partially surrounded by a plurality of channel regions spaced apart from each other in the first direction, where a plurality of capacitor structures and the plurality of channel regions are aligned in the first direction, and where the plurality of capacitor structures are spaced apart from the plurality of channel regions in the first direction, a bit line at one side of the plurality of channel regions and extending in the third direction, a plate electrode between two word lines of the plurality of word lines that adjacent to each other in the second direction, and an extension plate electrode contacting the plate electrode and at least one capacitor structure.

According to an aspect of an example embodiment, a semiconductor device may include a plurality of word lines on a substrate in a first direction perpendicular to a surface of the substrate, the plurality of word lines arranged in a second direction intersecting the first direction and a third direction intersecting the second direction, where each word line of the plurality of word lines is at least partially surrounded by a plurality of channel regions each having a ring shape, and spaced apart from each other in the first direction, where a plurality of capacitor structures and the plurality of channel regions are aligned in the first direction, and where the plurality of capacitor structures are spaced apart from the plurality of channel regions in the first direction, a bit line at one side of the plurality of channel regions and extending in the third direction, a contact between a first capacitor structure of the plurality of capacitor structures and a first channel region of the plurality of channel regions that are adjacent to each other in the first direction, a plate electrode between two word lines of the plurality of word lines that adjacent to each other in the second direction, and an extension plate electrode having a ring shape and at least partially surrounding the plate electrode, the extension plate electrode contacting the plate electrode and at least one capacitor structure of the plurality of capacitor structures.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a perspective view illustrating a semiconductor device according to one or more embodiments;

FIG. 2 is a cross-sectional view illustrating a semiconductor device according to one or more embodiments;

FIG. 3A is a plan view at a first vertical level of FIG. 2 according to one or more embodiments;

FIG. 3B is a plan view at a second vertical level of FIG. 2 according to one or more embodiments;

FIG. 3C is a plan view at a third vertical level of FIG. 2 according to one or more embodiments;

FIG. 3D is a plan view at a fourth vertical level of FIG. 2 according to one or more embodiments;

FIGS. 4A and 4B are plan views illustrating semiconductor devices according to one or more embodiments;

FIG. 5 is a perspective view illustrating a semiconductor device according to one or more embodiments;

FIG. 6 is a plan view of the semiconductor device of FIG. 5 at a third vertical level according to one or more embodiments;

FIG. 7 is a perspective view illustrating a semiconductor device according to one or more embodiments;

FIG. 8 is a plan view of the semiconductor device of FIG. 7 at a third vertical level according to one or more embodiments; and

FIGS. 9A, 9B, 10A, 10B, 11A, 11B, 12A, 12B, 13A, 13B, 14A, 14B, 15A, 15B, 16A, 16B, 17A, 17B, 18A, 18B, 19A, and 19B are diagrams illustrating manufacturing methods of a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, unless indicated otherwise, the term “surrounding” and equivalents thereof may include a full surrounding across all directions or a partial surrounding across fewer than all directions, as will be understood by one of ordinary skill in the art from the disclosure herein. As used herein, unless indicated otherwise, the term “covering” and equivalents thereof may include a full covering or a partial covering, as will be understood by one of ordinary skill in the art from the disclosure herein

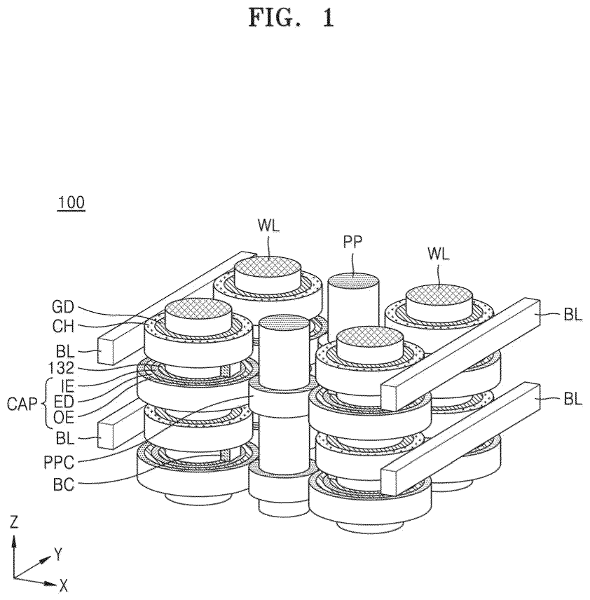

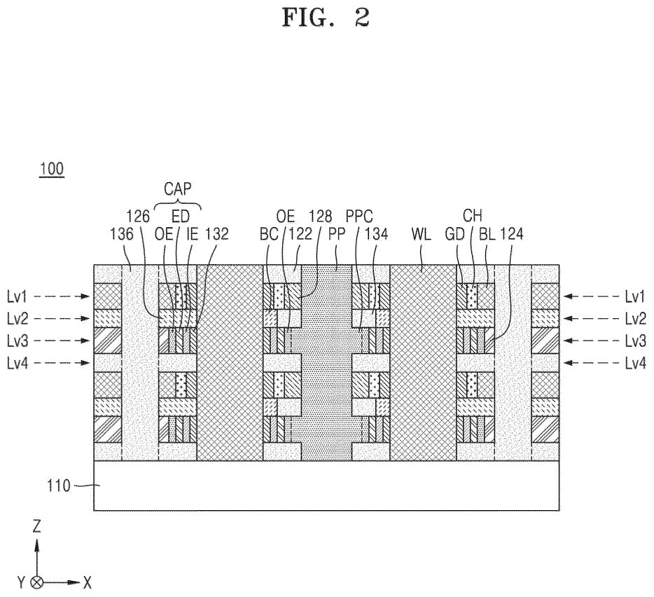

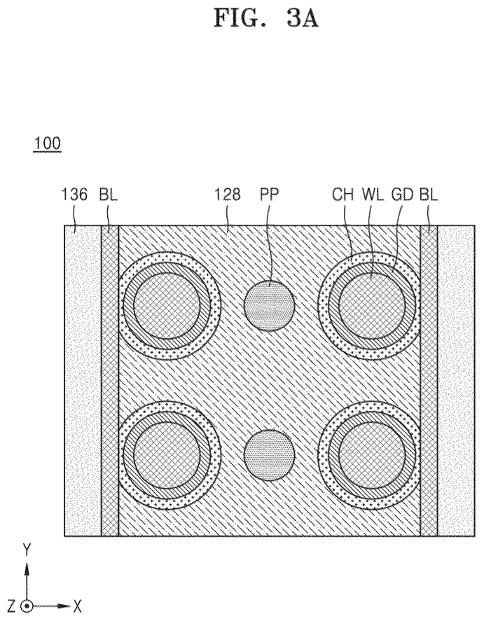

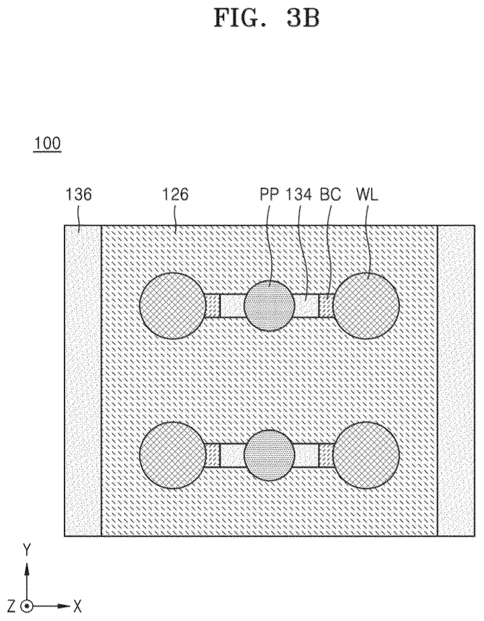

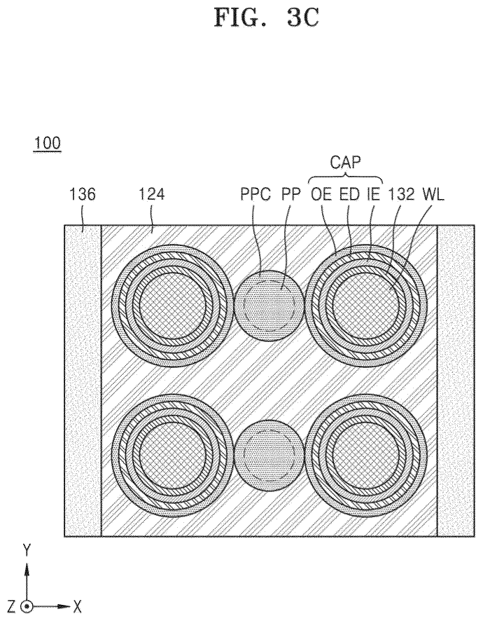

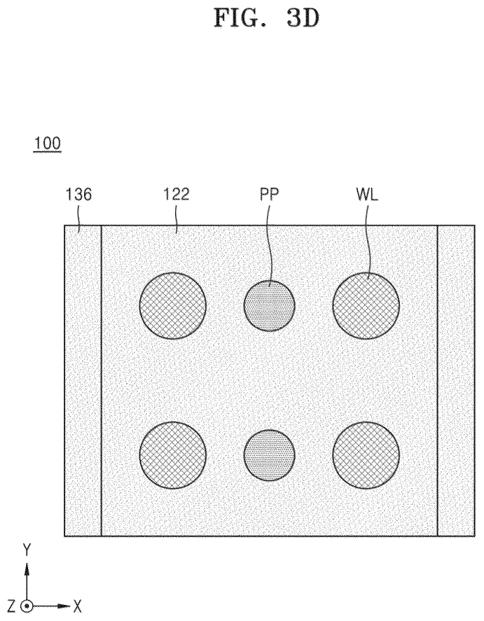

FIG. 1 is a perspective view illustrating a semiconductor device 100 according to one or more embodiments. FIG. 2 is a cross-sectional view illustrating the semiconductor device 100 according to one or more embodiments. FIG. 3A is a plan view at a first vertical level Lv1 of FIG. 2 according to one or more embodiments, FIG. 3B is a plan view at a second vertical level Lv2 of FIG. 2 according to one or more embodiments, FIG. 3C is a plan view at a third vertical level Lv3 of FIG. 2 according to one or more embodiments, and FIG. 3D is a plan view at a fourth vertical level Lv4 of FIG. 2 according to one or more embodiments.

Referring to FIGS. 1, 2, 3A, 3B, 3C, and 3D, the semiconductor device 100 may include a substrate 110, a plurality of word lines WL disposed on the substrate 110, a plurality of channel regions CH surrounding each of the plurality of word lines WL, and a plurality of capacitor structures CAP surrounding each of the plurality of word lines WL.

The substrate 110 may include a semiconductor material, such as a group IV semiconductor, a group III-V compound semiconductor, or a group II-VI oxide semiconductor. For example, the group IV semiconductor may include silicon (Si), germanium (Ge), or silicon-germanium. The substrate 110 may be also provided as a bulk wafer or an epitaxial layer. In one or more embodiments, the substrate 110 may include a silicon-on-insulator (SOI) substrate, or a germanium-on-insulator (GeOI) substrate.

A peripheral circuit and a wiring layer connected to the peripheral circuit may be further formed in some regions of the substrate 110. For example, the peripheral circuit may include a planar-type metal-oxide-semiconductor (MOS) field effect transistor (FET) (MOSFET) constituting a sub-word line driver, a sense amplifier, etc., but is not limited thereto. Also, a lower insulating layer disposed on the substrate 110 and covering the peripheral circuit and the wiring layer may be further formed.

The plurality of word lines WL may each extend lengthwise in a vertical direction (e.g., Z direction) on the substrate 110. The plurality of word lines WL may be arranged and spaced apart from each other in a first horizontal direction (e.g., X direction) and a second horizontal direction (e.g., Y direction) on the substrate 110.

The plurality of word lines WL may each include at least one of, for example, a doped semiconductor material, a conductive metal nitride, a metal, and a metal-semiconductor compound.

The plurality of channel regions CH may each surround one of the plurality of word lines WL. The plurality of channel regions CH surrounding one word line WL may be spaced apart from each other in the vertical direction (e.g., Z direction) and may overlap each other in the vertical direction (e.g., Z direction). In one or more embodiments, the channel region CH may have a ring shape that surrounds the word line WL. The plurality of channel regions CH may each include a source/drain region. For example, the source/drain region may include a semiconductor material doped with impurities.

In one or more embodiments, the plurality of channel regions CH may each be made of polysilicon. In one or more embodiments, the plurality of channel regions CH may each include an amorphous metal oxide, a polycrystalline metal oxide, or a combination of the amorphous metal oxide and the polycrystalline metal oxide. For example, the plurality of channel regions CH may each include at least one of In—Ga-based oxide (IGO), In—Zn-based oxide (IZO), or In—Ga—Zn-based oxide (IGZO).

A plurality of gate insulating films GD may be located between the word line WL and the plurality of channel regions CH surrounding the word line WL. The channel region CH may be horizontally spaced apart from the word line WL with the gate insulating film GD located therebetween. In one or more embodiments, the gate insulating film GD may have a ring shape that surrounds the word line WL. In one or more embodiments, the plurality of gate insulating films GD may each include a silicon oxide (SiO₂), a silicon nitride (Si₃N₄), a silicon oxynitride (SiOxNy), or a combination thereof. In one or more embodiments, the plurality of gate insulating films GD may each include a high dielectric material. The high dielectric material may have a dielectric constant of about 10 to about 25. The high dielectric material may include, for example, a hafnium oxide (HfO), an aluminum oxide (Al₂O₃), a zirconium oxide (e.g., ZrO₂), or a combination thereof, but is not limited thereto.

A plurality of bit lines BL may be arranged at one side of each of the plurality of channel regions CH in the first horizontal direction (e.g., X direction). The plurality of bit lines BL may contact each of the plurality of channel regions CH at one side of each of the plurality of channel regions CH. The plurality of bit lines BL may each extend lengthwise in the second horizontal direction (e.g., Y direction). The plurality of bit lines BL may be spaced apart from each other in the vertical direction (e.g., Z direction) and may overlap each other in the vertical direction (e.g., Z direction). In one or more embodiments, the bit line BL may be at the same vertical level as the channel region CH.

An inter-cell group insulating film 136 may be arranged at a side of each of the plurality of bit lines BL that does not contact the channel region CH. The inter-cell group insulating film 136 may extend in the vertical direction (e.g., Z direction) and may extend lengthwise in the second horizontal direction (e.g., Y direction). The inter-cell group insulating film 136 may contact each of the plurality of bit lines BL. The inter-cell group insulating film 136 may include, for example, a silicon oxide (SiO₂), but is not limited thereto.

In addition, a polysilicon layer 124 may be arranged between the inter-cell group insulating film 136 and a capacitor structure CAP that are adjacent to each other in the horizontal direction, and a second insulating layer 126 may be arranged between the inter-cell group insulating film 136 and the word line WL that are adjacent to each other in a horizontal direction (e.g., in the X direction and/or Y direction). The polysilicon layer 124 may be at the same vertical level as the capacitor structure CAP, and the second insulating layer 126 may be at the same vertical level as a contact BC. The polysilicon layer 124 may include, for example, a doped polysilicon. The second insulating layer 126 may include, for example, a doped silicon nitride.

The plurality of capacitor structures CAP may each surround one of the plurality of word lines WL and may be arranged between the plurality of channel regions CH. The plurality of capacitor structures CAP surrounding one word line WL may be spaced apart from each other in the vertical direction (e.g., Z direction) and may overlap each other in the vertical direction (e.g., Z direction). Also, each of the plurality of capacitor structures CAP surrounding one word line WL and each of the plurality of channel regions CH surrounding the one word line WL may be spaced apart from each other in the vertical direction (e.g., Z direction), and may overlap each other in the vertical direction (e.g., Z direction). That is, the width of the capacitor structures CAP may be greater than the width of the channel regions

CH in the X direction and/or the Y direction. In one or more embodiments, each capacitor structure CAP may be at a different vertical level than that of each channel region CH. In one or more embodiments, the capacitor structure CAP may have a ring shape that surrounds the word line WL. The plurality of capacitor structures CAP may each include a first electrode IE, a capacitor dielectric film ED, and a second electrode OE. The first electrode IE, the capacitor dielectric film ED, and the second electrode OE may have a ring shape surrounding the word line WL. In one or more embodiments, the first electrode IE, the capacitor dielectric film ED, and the second electrode OE may be at the same vertical level.

In one or more embodiments, the first electrode IE and the second electrode OE may each include a doped semiconductor material, a conductive metal nitride such as a titanium nitride (TiN), a tantalum nitride (TaN), a niobium nitride (NbN), or a tungsten nitride (WNx), a metal such as ruthenium (Ru), iridium (Ir), titanium (Ti), or tantalum (Ta), and a conductive metal oxide such as an iridium oxide (IrO₂) or a niobium oxide (Nb₂O₅).

In one or more embodiments, the capacitor dielectric film ED may include a high dielectric material. The high dielectric material may include, for example, a hafnium oxide (HfO), an aluminum oxide (Al₂O₃), a zirconium oxide (e.g., ZrO₂), or a combination thereof, but is not limited thereto. In one or more embodiments, the capacitor dielectric film ED may include a ferroelectric material. The ferroelectric material may include at least one of, for example, hafnium (Hf), zirconium (Zr), silicon (Si), yttrium (Yt), aluminum (Al), gadolinium (Gd), strontium (Sr), lanthanum (La), titanium (Ti), scandium (Sc), and oxides thereof.

A plurality of first buried insulating layers 132 may be located between the word line WL and the plurality of capacitor structures CAP surrounding the word line WL. The capacitor structure CAP may be horizontally spaced apart (e.g., in the X direction and/or Y direction) from the word line WL with the first buried insulating layer 132 located therebetween. In one or more embodiments, the first buried insulating layer 132 may have a ring shape that surrounds the word line WL. The first buried insulating layer 132 may include, for example, a silicon oxide (SiO₂).

In the semiconductor device 100, one memory cell may include one channel region CH, one capacitor structure CAP adjacent to the one channel region CH in the vertical direction (e.g., Z direction) and connected to the one channel region CH by the contact BC to be described below, one bit line BL arranged at one side of the one channel region CH, and one word line WL surrounded by the one channel region CH and the one capacitor structure CAP. Also, the semiconductor device 100 may include a plurality of memory cells each including the above-described construction and repeatedly arrayed in the first horizontal direction (e.g., X direction), the second horizontal direction (e.g., Y direction), and the vertical direction (e.g., Z direction).

A plate electrode PP may be arranged between two word lines WL that are adjacent to each other in the first horizontal direction (e.g., X direction). The plate electrode PP may extend lengthwise in the vertical direction (e.g., Z direction). For example, the plate electrode PP may have a cylindrical shape.

A plurality of extension plate electrodes PPC surrounding the plate electrode PP may be disposed on the surface of the plate electrode PP. The plurality of extension plate electrodes PPC may each surround the plate electrode PP. The plurality of extension plate electrodes PPC surrounding one plate electrode PP may be spaced apart from each other in the vertical direction (e.g., Z direction) and may overlap each other in the vertical direction (e.g., Z direction). In one or more embodiments, the extension plate electrode PPC may have a ring shape that surrounds the plate electrode PP. An inner side of the extension plate electrode PPC may contact the surface of the plate electrode PP, and an outer side of the extension plate electrode PPC may contact the second electrode OE of the capacitor structure CAP. In one or more embodiments, the extension plate electrode PPC may be at the same vertical level as the capacitor structure CAP.

One plate electrode PP may be connected, via the extension plate electrode PPC surrounding the one plate electrode PP, to the second electrode OE of each of the plurality of capacitor structures CAP surrounding two word lines WL adjacent to the one plate electrode PP in the first horizontal direction (e.g., X direction). That is, the plurality of capacitor structures CAP surrounding each of the two word lines WL adjacent to the one plate electrode PP in the first horizontal direction (e.g., X direction) may share the one plate electrode PP. Also, a second electrode OE of one capacitor structure CAP included in the plurality of capacitor structures CAP surrounding each of the two word lines WL, one extension plate electrode PPC contacting the second electrode OE of the one capacitor structure CAP, and a plate electrode PP connected to the second electrode OE of the one capacitor structure CAP by the one extension plate electrode PPC may function as an electrode of the one capacitor structure CAP, together.

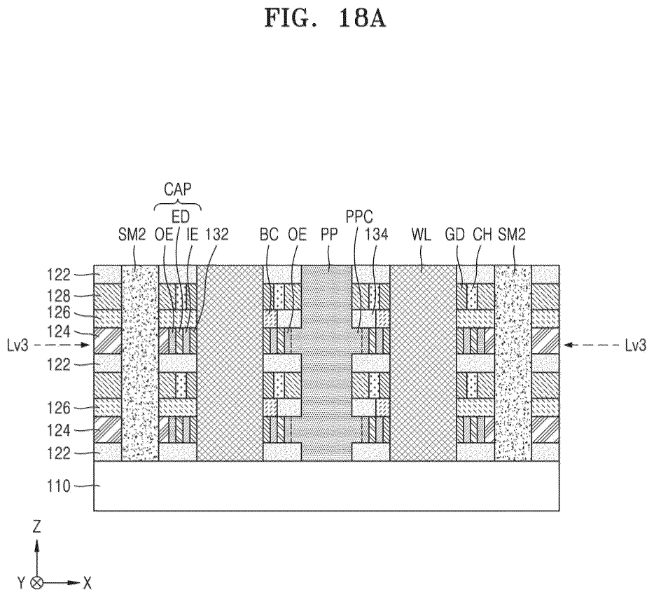

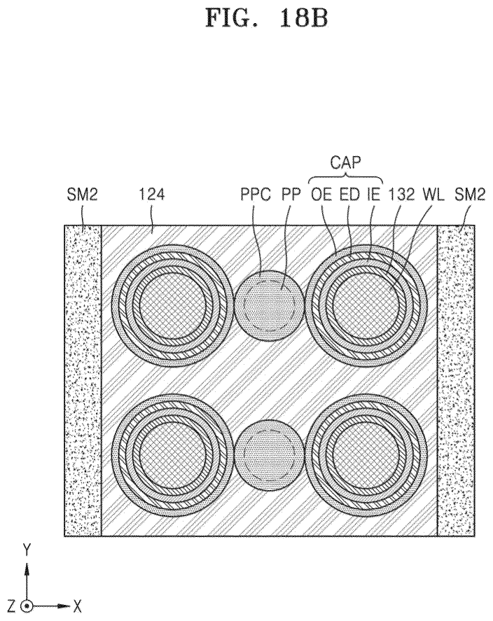

In FIGS. 1 to 3D, the plate electrode PP and the extension plate electrode PPC are illustrated as separate components with a boundary distinction between the plate electrode PP and the extension plate electrode PPC, but embodiments are not limited thereto. For example, the plate electrode PP and the extension plate electrode PPC may be formed integrally as described below with reference to FIGS. 18A and 18B, and the plate electrode PP and the extension plate electrode PPC may also become integral without the boundary distinction therebetween.

The contact BC may be arranged between the word line WL and the plate electrode PP that are adjacent to each other in the first horizontal direction (e.g., X direction). An upper surface of the contact BC may contact one channel region CH surrounding the word line WL, and a lower surface of the contact BC may contact a first electrode IE of one capacitor structure CAP that surrounds the word line WL and is adjacent to the one channel region CH in the vertical direction (e.g., Z direction). The one channel region CH and the one capacitor structure CAP, which are adjacent to each other in the vertical direction (e.g., Z direction), may be connected to each other through the contact BC. In one or more embodiments, the contact BC may include at least one of a doped semiconductor material, a conductive metal nitride, a metal, and a metal-semiconductor compound.

A second buried insulating layer 134 may be located between the contact BC and the plate electrode PP. One side of the second buried insulating layer 134 may contact the contact BC, and the other side, facing the one side, of the second buried insulating layer 134 may contact the plate electrode PP. The second buried insulating layer 134 may insulate the plate electrode PP from the contact BC. The second buried insulating layer 134 may include, for example, a silicon oxide (SiO₂).

A first insulating layer 122 may be arranged between the word line WL and the plate electrode PP that are adjacent to each other in the first horizontal direction (e.g., X direction) and between the word line WL and the inter-cell group insulating film 136 that are adjacent to each other in the first horizontal direction (e.g., X direction). The first insulating layer 122 may be at a different vertical level from the channel region CH, the capacitor structure CAP, and the contact BC. The first insulating layer 122 may include, for example, a silicon oxide (SiO₂).

A third insulating layer 128 may be arranged between the plurality of channel regions CH surrounding the word line WL and the plate electrode PP adjacent to the word line WL in the first horizontal direction (e.g., X direction). The third insulating layer 128 may insulate the plate electrode PP from the channel region CH. The third insulating layer 128 may include, for example, a silicon nitride (Si₃N₄).

The semiconductor device 100 according to one or more embodiments may include the word line WL disposed on the substrate 110 and extending in the vertical direction (e.g., Z direction), the plurality of channel regions CH surrounding the word line WL and spaced apart from each other in the vertical direction (e.g., Z direction), and the plurality of capacitor structures CAP surrounding the word line WL and arranged between the plurality of channel regions CH. The capacitor structure CAP may be arranged to overlap the channel region CH in the vertical direction rather than in the horizontal direction, thereby reducing the horizontal area occupied by one memory cell including one capacitor structure CAP and one channel region CH, and thus improving the degree of integration of the semiconductor device 100. That is, the width of the capacitor structure CAP may be greater than the width of the channel region CH in the X direction and/or the Y direction.

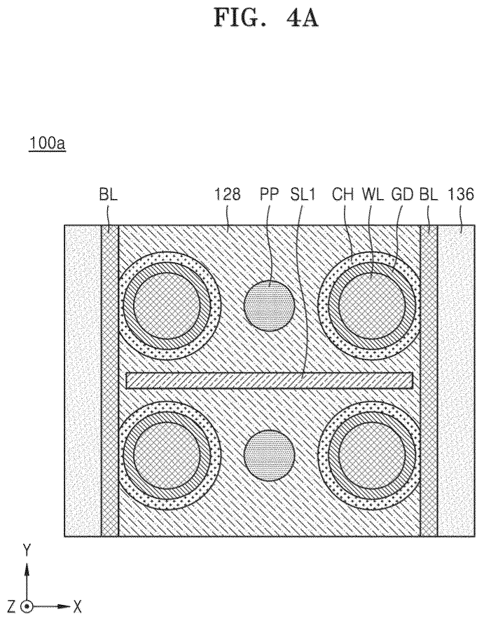

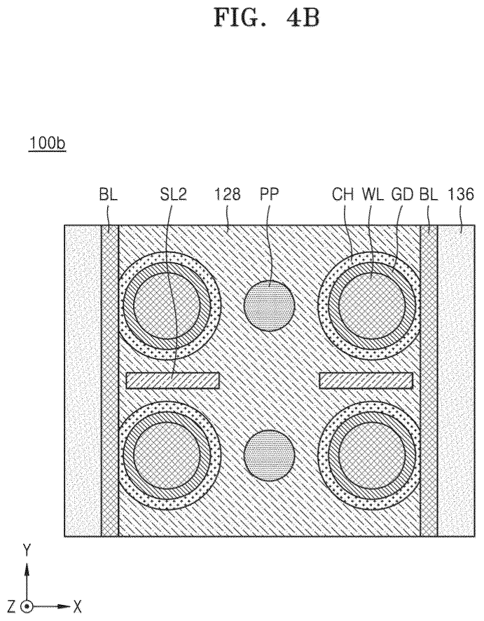

FIG. 4A is a plan view of a semiconductor device 100a according to one or more embodiments. FIG. 4B is a plan view of a semiconductor device 100b according to one or more embodiments. Specifically, FIG. 4A is the plan view of the semiconductor device 100a at a first vertical level Lv1 (see FIG. 2) and FIG. 4B is the plan view of the semiconductor device 100b at the first vertical level Lv1 (see FIG. 2). Aspects of the semiconductor device 100a illustrated in FIG. 4A and aspects of the semiconductor device 100b illustrated in FIG. 4B may be similar with each component of the semiconductor device 100 described with reference to FIGS. 1, 2, 3A, 3B, 3C, and 3D and thus, repeated descriptions may be omitted.

Referring to FIG. 4A, the semiconductor device 100a may have generally the same construction as the semiconductor device 100 illustrated in FIGS. 1, 2, 3A, 3B, 3C, and 3D, except that the semiconductor device 100a includes a first shield structure SL1.

The first shield structure SL1 may be arranged between word lines WL adjacent to each other in the second horizontal direction (e.g., Y direction). In one or more embodiments, the first shield structure SL1 may be at the same vertical level as the channel region CH. Between two bit lines BL adjacent to each other in the first horizontal direction (e.g., X direction), one first shield structure SL1 may be arranged between two pairs of word lines WL adjacent to each other in the second horizontal direction (e.g., Y direction), and the first shield structure SL1 may be extended relatively lengthwise in the first horizontal direction (e.g., X direction) compared to a second shield structure SL2 of the semiconductor device 100b illustrated in FIG. 4B. The first shield structure SL1 may prevent interference between the word lines WL adjacent to each other in the second horizontal direction (e.g., Y direction). In one or more embodiments, the first shield structure SL1 may include a conductive material. For example, the conductive material may include a metal.

Referring to FIG. 4B, the semiconductor device 100b may have generally the same construction as the semiconductor device 100 illustrated in FIGS. 1, 2, 3A, 3B, 3C, and 3D, except that the semiconductor device 100b includes a second shield structure SL2.

The second shield structure SL2 may be arranged between word lines WL adjacent to each other in the second horizontal direction (e.g., Y direction). In one or more embodiments, the second shield structure SL2 may be at the same vertical level as the channel region CH. Between two bit lines BL adjacent to each other in the first horizontal direction (e.g., X direction), two second shield structures SL2 may be arranged respectively between two pairs of word lines WL adjacent to each other in the second horizontal direction (e.g., Y direction), and the two second shield structures SL2 may be spaced apart from each other in the first horizontal direction (e.g., X direction). The second shield structure SL2 may be extended relatively short in the first horizontal direction (e.g., X direction) compared to the first shield structure SL1 of the semiconductor device 100a illustrated in FIG. 4A. The second shield structure SL2 may prevent interference between the word lines WL adjacent to each other in the second horizontal direction (e.g., Y direction). In one or more embodiments, the second shield structure SL2 may include a conductive material. For example, the conductive material may include a metal.

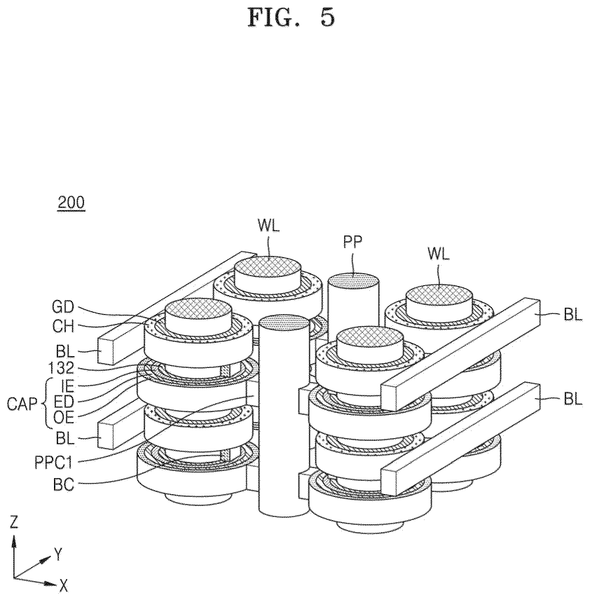

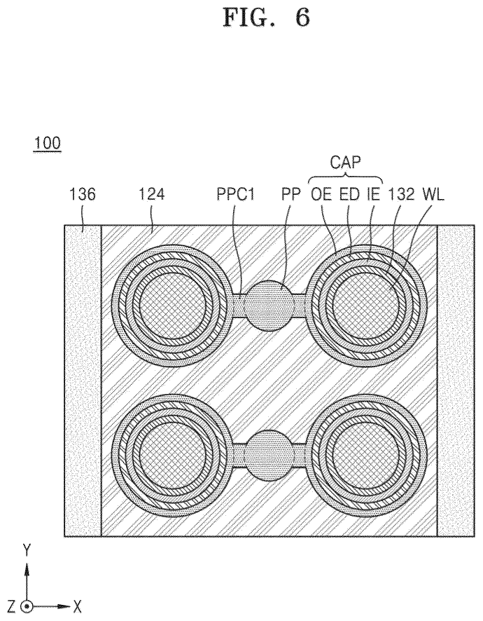

FIG. 5 is a perspective view illustrating a semiconductor device 200 according to one or more embodiments. FIG. 6 is a plan view of the semiconductor device 200 of FIG. 5 at a third vertical level (see FIG. 2) according to one or more embodiments. Aspects the semiconductor device 200 illustrated in FIGS. 5 and 6 may be similar to aspects of the semiconductor device 100 described with reference to FIGS. 1, 2, 3A, 3B, 3C, and 3D and thus, repeated descriptions may be omitted.

Referring to FIGS. 5 and 6, the semiconductor device 200 may have substantially the same construction as the semiconductor device 100 illustrated in FIGS. 1, 2, 3A, 3B, 3C, and 3D, except that the semiconductor device 200 includes an extension plate electrode PPC1 having a rectangular shape.

A plurality of extension plate electrodes PPC1 may each protrude from the surface of the plate electrode PP and extend in the first horizontal direction (e.g., X direction) toward each of the plurality of capacitor structures CAP surrounding each of two word lines WL adjacent to the plate electrode PP in the first horizontal direction (e.g., X direction). One side of the extension plate electrode PPC1 may contact the surface of the plate electrode PP, and the other side, facing the one side in the first horizontal direction (e.g., X direction), of the extension plate electrode PPC1 may contact the second electrode OE of the capacitor structure CAP. The plurality of extension plate electrodes PPC1 may be spaced apart from each other in the vertical direction (e.g., Z direction) and overlap each other in the vertical direction (e.g., Z direction). In one or more embodiments, the extension plate electrode PPC1 may be at the same vertical level as the capacitor structure CAP. In one or more embodiments, the extension plate electrode PPC1 may have a rectangular shape.

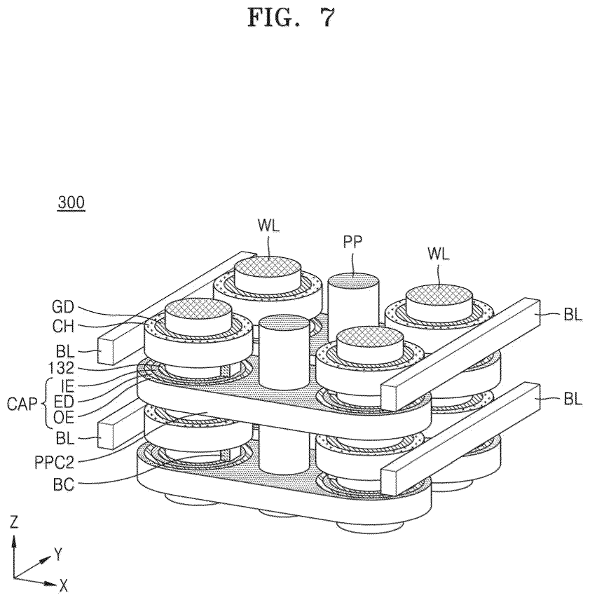

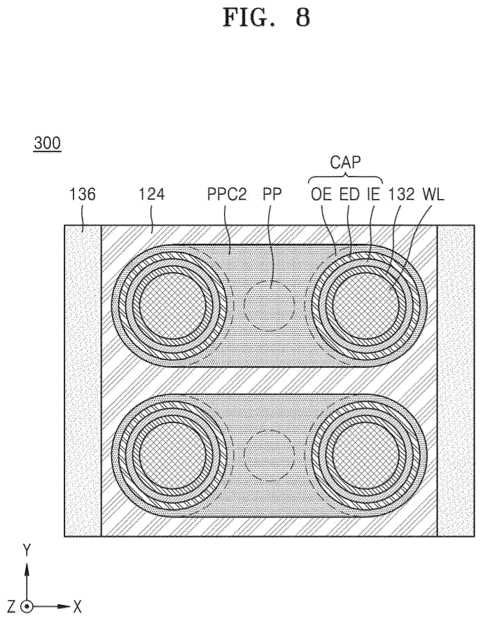

FIG. 7 is a perspective view illustrating a semiconductor device 300 according to one or more embodiments. FIG. 8 is a plan view of the semiconductor device 300 of FIG. 7 at a third vertical level (see FIG. 2) according to one or more embodiments. Aspects of the semiconductor device 300 illustrated in FIGS. 7 and 8 may be the same or similar to aspects of the semiconductor device 100 described with reference to FIGS. 1, 2, 3A, 3B, 3C, and 3D and thus, repeated descriptions may be omitted.

Referring to FIGS. 7 and 8, the semiconductor device 300 may have substantially the same construction as the semiconductor device 100 illustrated in FIGS. 1, 2, 3A, 3B, 3C and 3D, except that the semiconductor device 300 includes an extension plate electrode PPC2 having a rectangular shape with curved side surfaces.

A plurality of extension plate electrodes PPC2 may surround the plate electrode PP. The plurality of extension plate electrodes PPC2 may be spaced apart from each other in the vertical direction (e.g., Z direction) and overlap each other in the vertical direction (e.g., Z direction). In one or more embodiments, the extension plate electrode PPC2 may be at the same vertical level as the capacitor structure CAP. In one or more embodiments, the extension plate electrode PPC2 may have a rectangular shape with curved side surfaces and an opening surrounding the plate electrode PP at the center of the extension plate electrode PPC2. The curved side surfaces of the extension plate electrode PPC2 may contact the second electrode OE of the capacitor structure CAP having the ring shape.

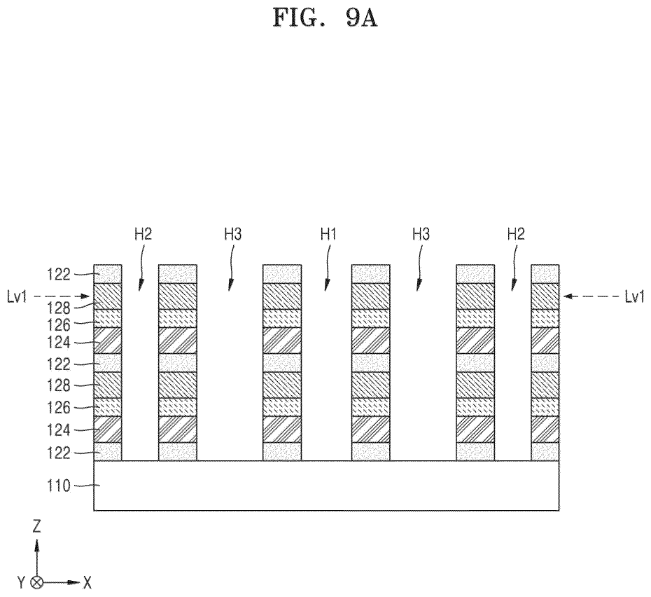

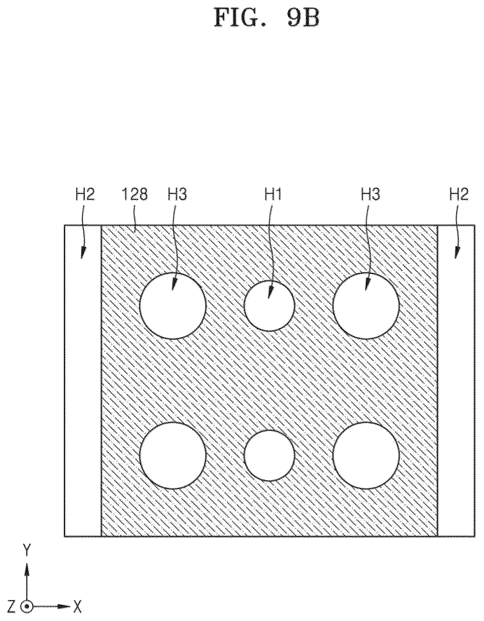

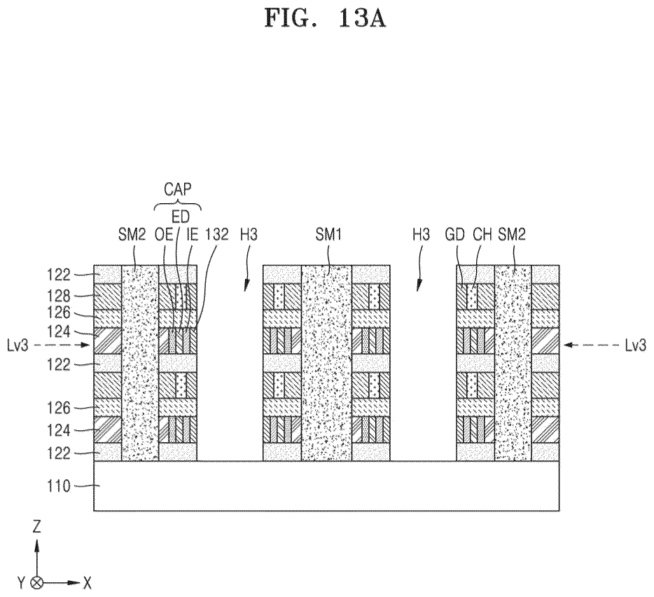

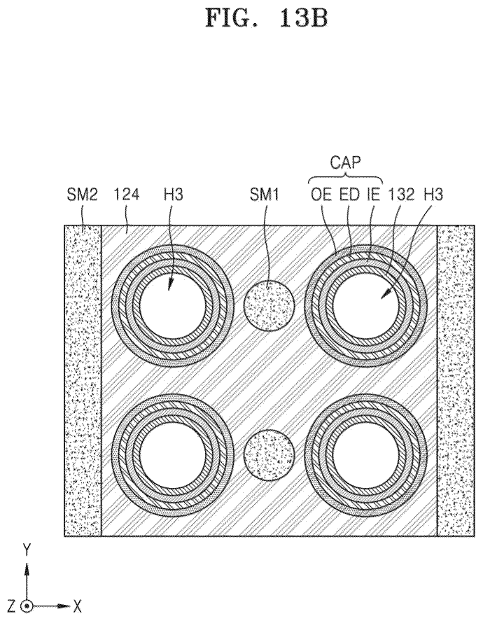

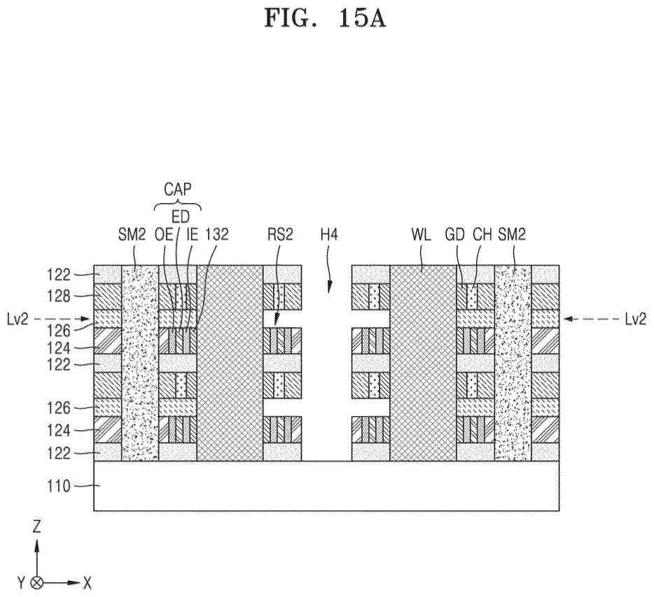

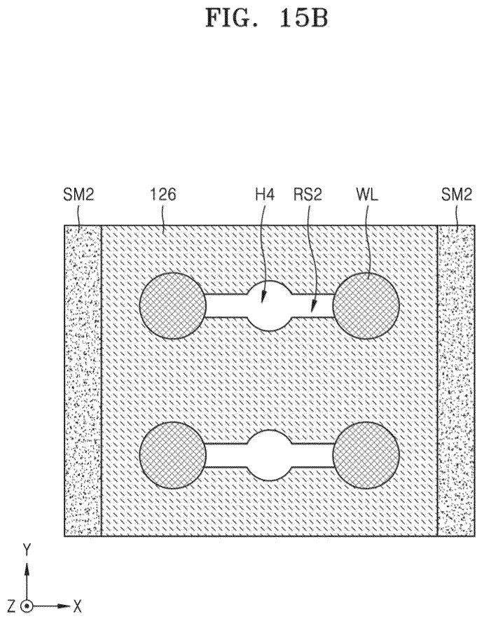

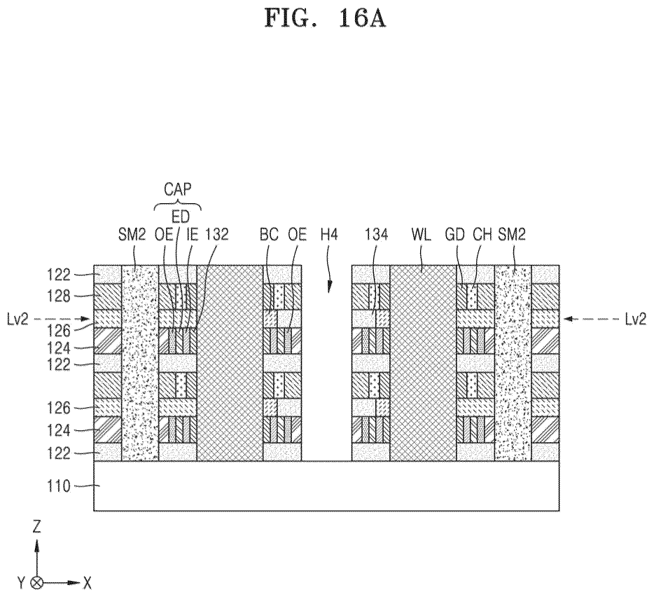

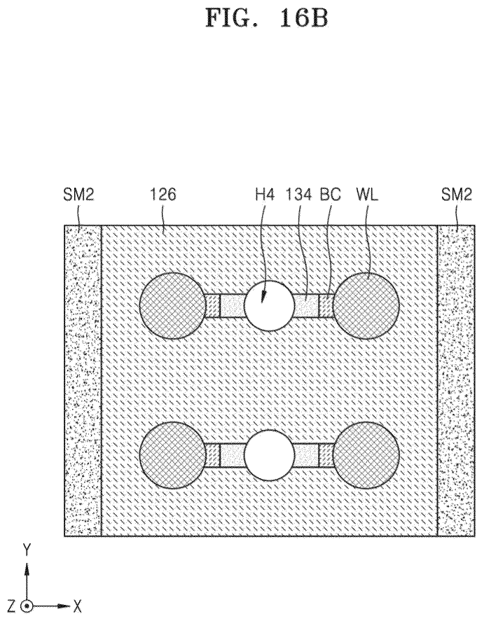

FIGS. 9A, 9B, 10A, 10B, 11A, 11B, 12A, 12B, 13A, 13B, 14A, 14B, 15A, 15B, 16A, 16B, 17A, 17B, 18A, 18B, 19A, and 19B are diagrams illustrating methods of manufacturing a semiconductor device 100, according to one or more embodiments. Specifically, FIGS. 9A, 10A, 11A, 12A, 13A, 14A, 15A, 16A, 17A, 18A, and 19A are cross-sectional views illustrating the method of manufacturing the semiconductor device 100 according to one or more embodiments, FIGS. 9B, 10B, 11B, 12B, and 19B are plan views at a first vertical level Lv1 (see FIG. 2) according to one or more embodiments, FIGS. 13B, 14B, and 17B and 18B are plan views at a third vertical level Lv3 (see FIG. 2) according to one or more embodiments, and FIGS. 15B and 16B are plan views at a second vertical level Lv2 (see FIG. 2) according to one or more embodiments.

Referring to FIGS. 9A and 9B, a first insulating layer 122, a polysilicon layer 124, a second insulating layer 126, and a third insulating layer 128 may be repeatedly stacked on a substrate 110. In one or more embodiments, the first insulating layer 122, the polysilicon layer 124, the second insulating layer 126, and the third insulating layer 128 may each include a material having an etch selectivity with respect to one another. For example, the first insulating layer 122 may include a silicon oxide (SiO₂), the polysilicon layer 124 may include polysilicon, the second insulating layer 126 may include a doped silicon nitride, and the third insulating layer 128 may include an undoped silicon nitride.

A first hole H1 and a third hole H3 penetrating the first insulating layer 122, the polysilicon layer 124, the second insulating layer 126, and the third insulating layer 128 in a vertical direction (e.g., Z direction) may be formed, and a second hole H2 penetrating the first insulating layer 122, the polysilicon layer 124, the second insulating layer 126, and the third insulating layer 128 in the vertical direction (e.g., Z direction) and extending lengthwise in a second horizontal direction (e.g., Y direction) may be formed.

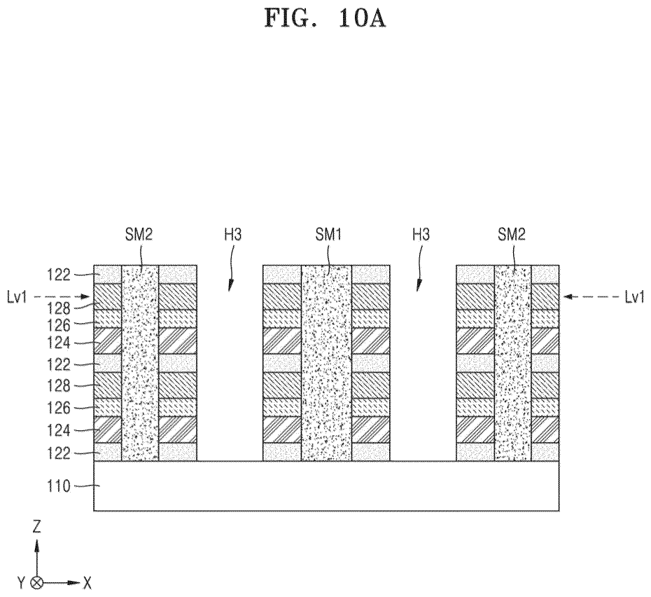

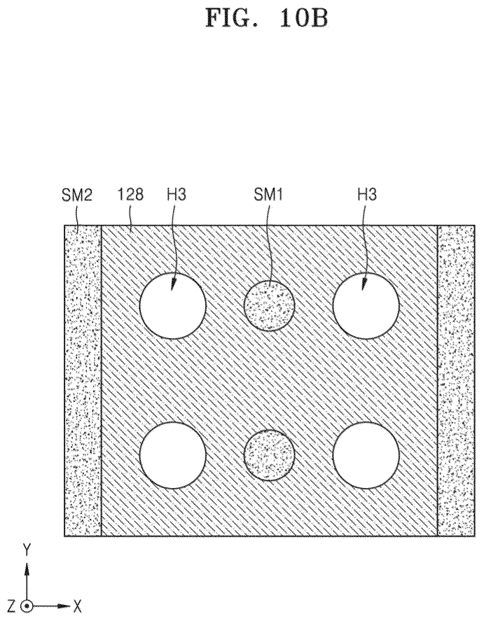

Referring to FIGS. 10A and 10B, a first sacrificial film SM1 filling the first hole H1 (see FIG. 9A) and a second sacrificial film SM2 filling the second hole H2 may be formed. The first sacrificial layer SM1 and the second sacrificial layer SM2 may include, for example, a silicon oxide (SiO₂).

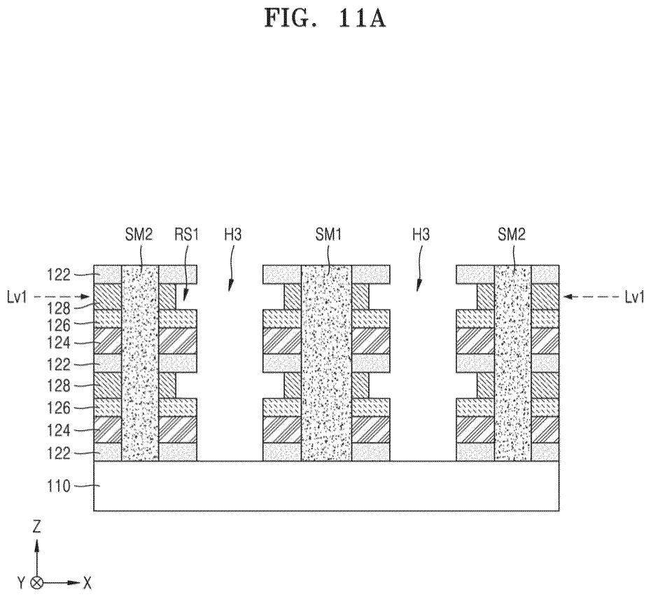

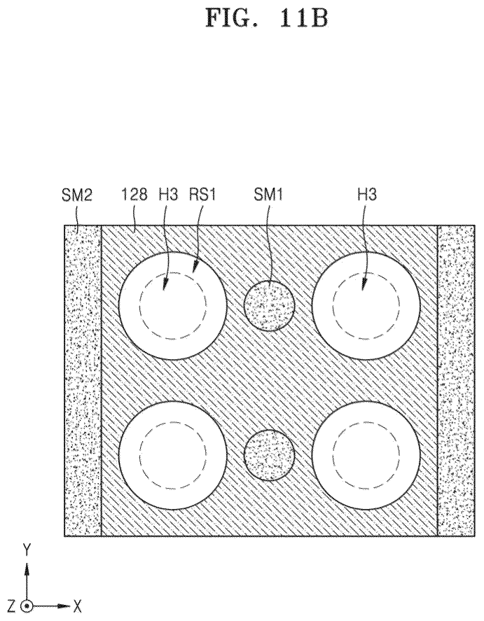

Referring to FIGS. 11A and 11B, a first recess RS1 may be formed by removing and horizontally recessing a portion of the third insulating layer 128 through the third hole H3. The first recess RS1 may be formed through an etching process. For example, the etching process may be performed using an etchant having an etch selectivity with respect to the third insulating layer 128. The first recess RS1 may communicate with the third hole H3. The first recess RS1 may have a ring shape that surrounds the third hole H3.

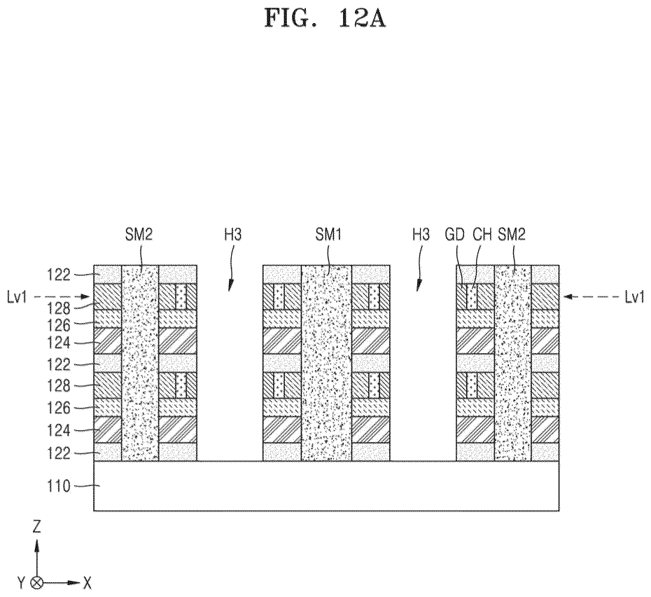

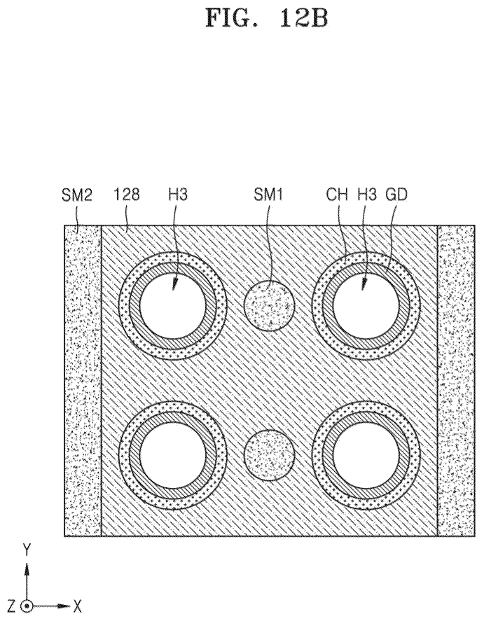

Referring to FIGS. 12A and 12B, a channel region CH and a gate insulating film GD sequentially filling the first recess RS1 (see FIG. 11A) may be formed. The channel region CH may cover the surface of the third insulating layer 128 exposed by the first recess RS1 (see FIG. 11A), and the gate insulating film GD may cover the surface of the channel region CH. Since the first recess RS1 has a ring shape that surrounds the third hole H3, the channel region CH and the gate insulating film GD filling the first recess RS1 may have a ring shape that surrounds the third hole H3.

Referring to FIGS. 13A and 13B, a recess may be formed by removing and horizontally recessing a portion of the polysilicon layer 124 through the third hole H3, and a capacitor structure CAP and a first buried insulating layer 132 sequentially filling the recess may be formed. The capacitor structure CAP may include a second electrode OE covering the surface of the polysilicon layer 124 exposed by the recess, a capacitor dielectric film ED covering the surface of the second electrode OE, and a first electrode IE covering the surface of the capacitor dielectric film ED. The recess may have a ring shape that surrounds the third hole H3, and the capacitor structure CAP filling the recess may also have a ring shape that surrounds the third hole H3. The first buried insulating layer 132 may cover the surface of the first electrode IE of the capacitor structure CAP.

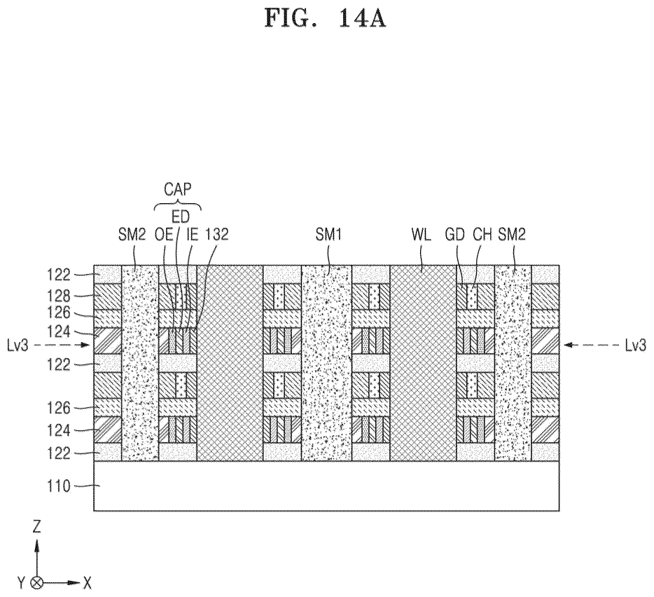

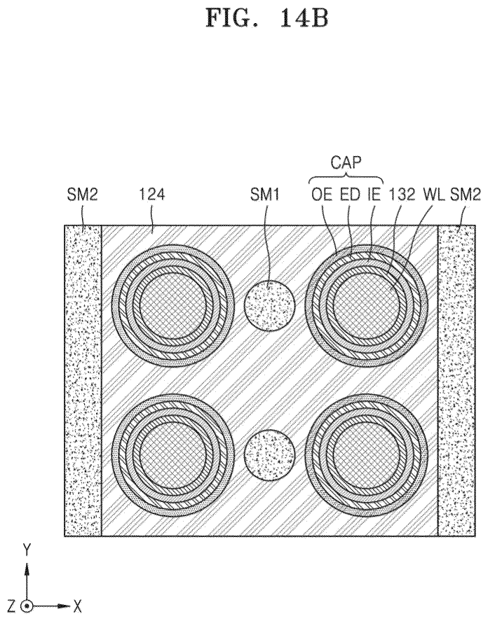

Referring to FIGS. 14A and 14B, a word line WL filling the third hole H3 (see FIG. 13A) may be formed.

Referring to FIGS. 15A and 15B, a fourth hole H4 may be formed by removing the first sacrificial film SM1 (see FIG. 14A), and a second recess RS2 may be formed by removing and horizontally recessing the second insulating layer 126 through the fourth hole H4. The second recess RS2 may expose a portion of a side face of the word line WL. The second recess RS2 may be formed through an etching process. For example, the etching process may be performed using an etchant having an etch selectivity with respect to the second insulating layer 126. The second recess RS2 may communicate with the fourth hole H4. The second recess RS2 may have a rectangular shape.

Referring to FIGS. 16A and 16B, a contact BC and a second buried insulating layer 134 sequentially filling the second recess RS2 (see FIG. 15A) may be formed. The contact BC may cover the surface of the word line WL exposed by the second recess RS2 (see FIG. 15A), and the second buried insulating layer 134 may cover the surface of the contact BC. An upper surface of the contact BC may contact a lower surface of the channel region CH, and a lower surface of the contact BC may contact the first electrode IE of the capacitor structure CAP. Since the second recess RS2 has a rectangular shape, the contact BC and second buried insulating layer 134 filling the second recess RS2 may have a rectangular shape.

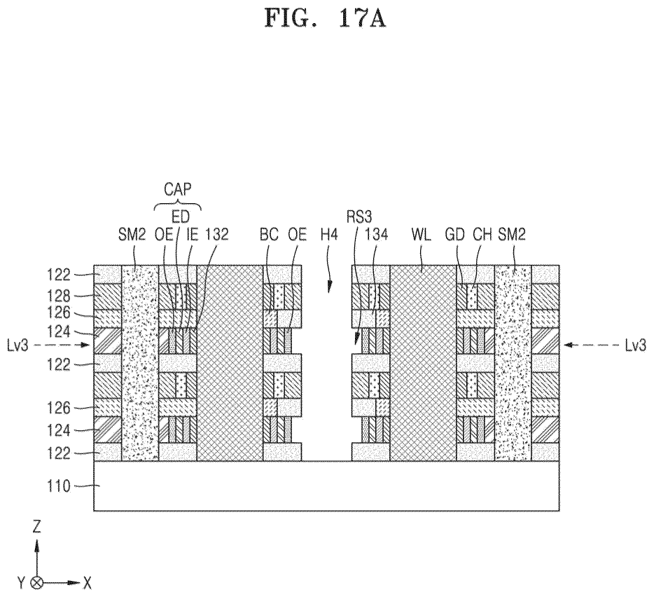

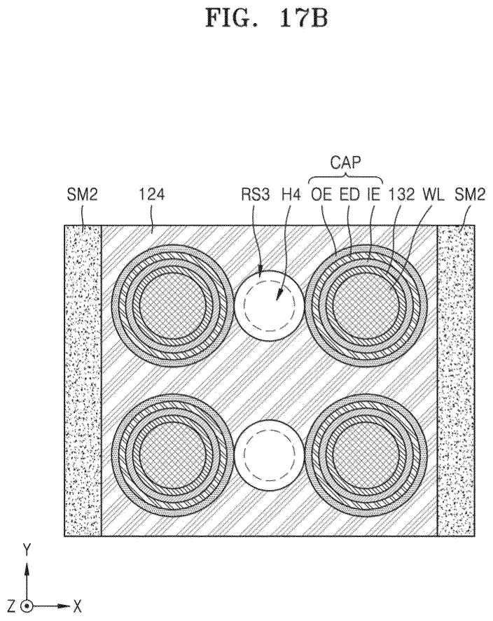

Referring to FIGS. 17A and 17B, a third recess RS3 may be formed by removing and horizontally recessing the polysilicon layer 124 through the fourth hole H4. The third recess RS3 may expose the second electrode OE of the capacitor structure CAP. The third recess RS3 may be formed through an etching process. For example, the etching process may be performed using an etchant having an etch selectivity with respect to the polysilicon layer 124. The third recess RS3 may communicate with the fourth hole H4. In one or more embodiments, the third recess RS3 may have a ring shape that surrounds the fourth hole H4. In one or more embodiments, the third recess RS3 may be also formed to have a rectangular shape that protrudes from the fourth hole H4. In this case, the semiconductor device 200 illustrated in FIGS. 5 and 6 may be manufactured by performing a process to be described below. In one or more embodiments, the third recess RS3 may be also formed to have a rectangular shape with curved side surfaces and surrounds the plate electrode PP at the center. In this case, the semiconductor device 300 illustrated in FIGS. 7 and 8 may be manufactured by performing the process to be described below.

Referring to FIGS. 18A and 18B, an extension plate electrode PPC filling the third recess RS3 (see FIG. 17A) may be formed, and a plate electrode PP filling the fourth hole H4 (FIG. 17A) may be formed. The plate electrode PP may be formed integrally with the extension plate electrode PPC. Accordingly, the plate electrode PP and the extension plate electrode PPC may be integrated.

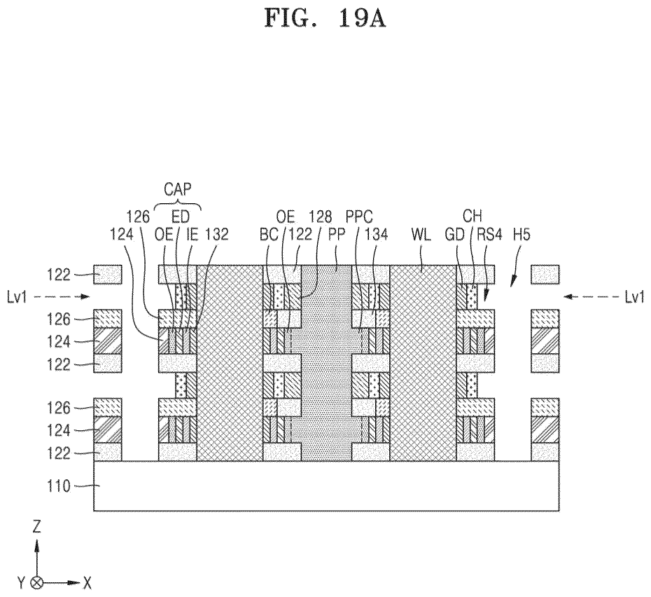

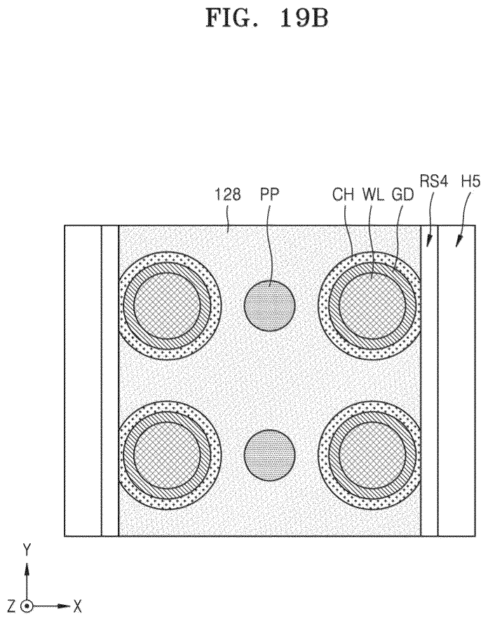

Referring to FIGS. 19A and 19B, a fifth hole H5 may be formed by removing the second sacrificial film SM2, and a fourth recess RS4 may be formed by removing and horizontally recessing the third insulating layer 128 exposed through the fifth hole H5. The fifth hole H5 and the fourth recess RS4 may extend lengthwise in the second horizontal direction (e.g., Y direction).

By forming a bit line BL filling the fourth recess RS4 (see FIG. 19A), and forming an inter-cell group insulating film 136 filling the fifth hole H5, the semiconductor device 100 described with reference to FIGS. 1 to 3D may be manufactured.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a word line on a substrate and extending in a first direction perpendicular to a surface of the substrate;
a plurality of channel regions at least partially surrounding the word line and spaced apart from each other in the first direction;
a bit line at one side of the plurality of channel regions, and extending in a second direction perpendicular to the first direction; and
a plurality of capacitor structures at least partially surrounding the word line,
wherein the plurality of capacitor structures and the plurality of channel regions are aligned in the first direction, and
wherein the plurality of capacitor structures are spaced apart from the plurality of channel regions in the first direction.

2. The semiconductor device of claim 1, wherein each of the plurality of capacitor structures have a ring shape.

3. The semiconductor device of claim 1, wherein each of the plurality of channel regions have a ring shape.

4. The semiconductor device of claim 1, wherein at least one channel region of the plurality of channel regions is at a level that is the same as a level as the bit line.

5. The semiconductor device of claim 1, wherein the plurality of capacitor structures are at different levels from the plurality of channel regions.

6. The semiconductor device of claim 1, further comprising a contact between a first capacitor structure of the plurality of capacitor structures that is adjacent to a first channel region of the plurality of channel regions in the first direction.

7. The semiconductor device of claim 6, wherein the first capacitor structure comprises a first electrode,
wherein an upper surface of the contact contacts the first channel region, and
wherein a lower surface of the contact contacts the first electrode.

8. A semiconductor device comprising:
a plurality of word lines on a substrate and extending in a first direction perpendicular to a surface of the substrate, the plurality of word lines arranged in a second direction intersecting the first direction and a third direction intersecting the second direction, wherein each word line of the plurality of word lines is at least partially surrounded by a plurality of channel regions spaced apart from each other in the first direction, wherein a plurality of capacitor structures and the plurality of channel regions are aligned in the first direction, and wherein the plurality of capacitor structures are spaced apart from the plurality of channel regions in the first direction;
a bit line at one side of the plurality of channel regions and extending in the third direction;
a plate electrode between two word lines of the plurality of word lines that adjacent to each other in the second direction; and
an extension plate electrode contacting the plate electrode and at least one capacitor structure.

9. The semiconductor device of claim 8, wherein the plurality of capacitor structures and the plurality of channel regions have a ring shape.

10. The semiconductor device of claim 8, wherein at least one channel region of the plurality of channel regions is at a level that is the same as a level of the bit line, and
wherein at least one channel region of the plurality of channel regions is at a level that is different from a level of at least one capacitor structure of the plurality of capacitor structures.

11. The semiconductor device of claim 8, further comprising a shield structure between word lines of the plurality of word lines that are adjacent to each other in the third direction.

12. The semiconductor device of claim 11, wherein the shield structure is at a level that is the same as a level of at least one channel region of the plurality of channel regions.

13. The semiconductor device of claim 8, wherein the extension plate electrode is at a level that is the same as a level of at least one capacitor structure of the plurality of capacitor structures.

14. The semiconductor device of claim 8, wherein the extension plate electrode has a ring shape that at least partially surrounds the plate electrode.

15. The semiconductor device of claim 8, wherein the extension plate electrode extends in the second direction from the surface of the plate electrode toward at least one capacitor structure of the plurality of capacitor structures.

16. The semiconductor device of claim 15, wherein the extension plate electrode has a rectangular shape.

17. The semiconductor device of claim 8, wherein the extension plate electrode has a rectangular shape with curved side surfaces,
wherein the extension plate electrode comprises an opening at a center of the extension plate electrode, and
wherein the extension plate electrode at least partially surrounds the plate electrode at the opening.

18. The semiconductor device of claim 17, wherein a first capacitor structure of the plurality of capacitor structures comprises a second electrode, and
wherein the curved side surfaces of the extension plate electrode contact the second electrode.

19. A semiconductor device comprising:
a plurality of word lines on a substrate in a first direction perpendicular to a surface of the substrate, the plurality of word lines arranged in a second direction intersecting the first direction and a third direction intersecting the second direction, wherein each word line of the plurality of word lines is at least partially surrounded by a plurality of channel regions each having a ring shape, and spaced apart from each other in the first direction, wherein a plurality of capacitor structures and the plurality of channel regions are aligned in the first direction, and wherein the plurality of capacitor structures are spaced apart from the plurality of channel regions in the first direction;
a bit line at one side of the plurality of channel regions and extending in the third direction;
a contact between a first capacitor structure of the plurality of capacitor structures and a first channel region of the plurality of channel regions that are adjacent to each other in the first direction;
a plate electrode between two word lines of the plurality of word lines that adjacent to each other in the second direction; and
an extension plate electrode having a ring shape and at least partially surrounding the plate electrode, the extension plate electrode contacting the plate electrode and at least one capacitor structure of the plurality of capacitor structures.

20. The semiconductor device of claim 19, wherein at least one channel region of the plurality of channel regions is at a level that is the same as a level of the bit line, and
wherein at least one capacitor structure of the plurality of capacitor structures is at a level that is the same as a level of the extension plate electrode.
